(19) United States
(12) Patent Application Publication
(10) Pub. No.: US 2007/0058468 A1
(43) Pub. Date: Mar. 15, 2007

(54) Shielded bitline architecture for dynamic random access memory (DRAM) arrays

(75) Inventor: Douglas Blaine Butler, Colorado Springs, CO (US)

Correspondence Address: HOGAN & HARTSON LLP, ONE TABOR CENTER, SUITE 1500, 1200 SEVENTEENTH ST, DENVER, CO, 80202, US

(73) Assignee: ProMOS Technologies PTE.LTD. Singapore

(21) Appl. No.: 11/224,541

(22) Filed: Sep. 12, 2005

(51) Int. Cl. G11C 7/02

(52) U.S. Cl. 365/210

(57) ABSTRACT

A shielded bitline architecture for DRAM memories and integrated circuit devices incorporating embedded DRAM is disclosed herein which comprises a shared sense amplifier, folded bitline array using a bitline from an adjacent, non-active subarray as a reference for a bitline in an active array.

### BACKGROUND OF THE INVENTION

The present invention relates, in general, to the field of integrated circuit (IC) memory devices including dynamic random access memory (DRAM) devices and other integrated circuit devices incorporating embedded DRAM. More particularly, the present invention relates to a shielded bitline architecture for DRAM arrays.

Many types of DRAM based devices, or integrated circuits including embedded memory arrays, are currently available including extended data out (“EDO”), synchronous DRAM (“SDRAM”), double data rate (“DDR”), DDR3 DRAM and the like. Regardless of configuration, the primary purpose of the DRAM is to store data. Functionally, data may be written to the memory, read from it or periodically refreshed to maintain the integrity of the stored data. In current high density designs, each DRAM memory cell generally comprises a single access transistor coupled to an associated capacitor (i.e. a 1T/1C design) that may be charged to store a value representative of either a logic level “1” or “0”. Data stored in these memory cells may be read out and written to them through columns of sense amplifiers coupled to complementary bitlines interconnecting rows of these cells.

DRAM architectures having both “open” and “folded” bitlines have been utilized. In open bitline designs, the complementary bitlines (BL and /BL; the latter sometimes indicated as BLB or bitline “bar”) extend in opposite direction from centrally located sense amplifiers and, while allowing for a relatively dense memory array layout, uneven wordline (WL) coupling can result. On the other hand, folded bitline architectures (i.e. BL and /BL extend parallel to each other from the sense amplifier) allow for relaxed sense amplifier layout pitch and more even wordline coupling. In this latter design, a memory cell is crossed by two wordlines and a single bitline. One of the wordlines is the “active” word line for the cell and the second is the “passing” word line at the gate of the adjacent cell. In this manner, the bitline and reference bitline can be adjacent to each other resulting in better matching and noise rejection.

Variations on the basic folded bitline architecture include the folded shared layout in which two pairs of complementary bitlines (each pair in a different subarray) are coupled to each of a centrally situated grouping of sense amplifiers and the interleaved architecture in which folded bitline pairs extending from adjacent groups of sense amplifiers are interleaved in the same subarray with those coupled to the opposite sense amplifier grouping.

In general, folded bitline DRAMs utilize a bitline in the same subarray as a reference bitline to enable accurate sensing of the stored data. In contrast, open bitline DRAMs use either a bitline in an adjacent array or a reference voltage generated by some other means as a reference voltage.

In order to prevent bitline-to-bitline coupling, folded bitline DRAMs typically incorporate twists in the bitlines. By using three bitline twists per subarray (i.e. twists at 25% and 75% of the length on a bitline pair and a twist at 50% on the adjacent bitline pair; i.e. “triple twist”), bitline-to-bitline coupling can be made “common mode” and, therefore, not serve to degrade the sense margin. However, the layout of these bitline twists consumes on-chip die area, usually on the order of six bitline pitches, thereby resulting in an increase in the required overall DRAM memory array area with a concomitant increase in device cost. Further, while bitline twists insure that bitline-to-bitline coupling is “common mode” they do not eliminate coupling.

### SUMMARY OF THE INVENTION

A shielded bitline architecture for DRAM memories and integrated circuit devices incorporating embedded DRAM is disclosed herein which comprises a folded bitline, shared sense amplifier array using a bitline from a non-active subarray as a reference for a bitline in an active array.

The shielded bitline DRAM architecture of the present invention eliminates the need for bitline twists, thereby conserving the on-chip die area required for the memory array and reducing concomitant device costs. Moreover, in comparison with the triple twist approach, the shielded bitline DRAM architecture of the present invention provides an overall effective power savings as well. Analysis of the former demonstrates a requirement for 3*(Cblc/2)*VBLH of charge per cycle versus only Cblc*VBLH of charge per cycle for the latter, where “Cblc” is the bitline-to-bitline coupling capacitance and VBLH is the bitline “high” voltage.

Particularly disclosed herein is an integrated circuit device incorporating a memory array including at least two subarrays of memory cells comprising at least one sense amplifier selectively coupleable to a first pair of complementary bitlines in a first one of the subarrays and a second pair of complementary bitlines in a second one of the subarrays. One of the first pair of complementary bitlines may be selectively operative as a reference line for one of the second pair of complementary bitlines.

Also particularly disclosed herein is an integrated circuit device incorporating a memory array including N subarrays of memory cells, wherein N>1, comprising a plurality of folded bitline shared sense amplifiers having a first pair of complementary bitlines in an active one of the N subarrays and a second pair of complementary bitlines in an inactive one of the N subarrays. First and second pairs of isolation transistors selectively couple each of the plurality of shared sense amplifiers to the first and second pairs of complementary bitlines with the isolation transistors being operative to couple each of the plurality of sense amplifiers such that one of the second pair of complementary bitlines serves as a reference for one of the first pair of complementary bitlines.

Further particularly disclosed herein is an integrated circuit device incorporating a memory array including a plurality of subarrays of memory cells comprising first and second columns of sense amplifiers and first and second pairs of complementary bitlines being coupleable to each of the sense amplifiers in the first and second columns. The first pairs of the complementary bitlines coupleable to the sense amplifiers of the first column being interleaved with the second pairs of the complementary bitlines coupleable to the sense amplifiers of the second column. The memory array is operative to drive every second one of the bitlines in an active one of the plurality of subarrays and every fourth one of the bitlines in adjacent inactive ones of the plurality of subarrays.

Still further particularly disclosed herein is a method for providing a reference in a folded bitline array of memory cells and shared sense amplifiers comprising asserting a wordline in a selected subarray of the memory cells to couple one of the memory cells to an associated bitline coupled to one of said sense amplifiers and utilizing another bitline also coupled to that one of the sense amplifiers in an adjacent subarray as a reference for the associated bitline.

Also further particularly disclosed herein is a method for providing a reference in a folded bitline, shared sense amplifier memory of an integrated circuit device comprising driving alternate ones of complementary bitlines in an active subarray of the memory and driving fourth ones of the complementary bitlines in an inactive adjacent subarray of the memory.

### BRIEF DESCRIPTION OF THE DRAWINGS

The aforementioned and other features and objects of the present invention and the manner of attaining them will become more apparent and the invention itself will be best understood by reference to the following description of a preferred embodiment taken in conjunction with the accompanying drawings, wherein:

FIG. 1 illustrates a portion of a representative folded bitline DRAM array in which the bitlines labeled BLB (bitline bar) are available to act as reference inputs to the sense amplifier for the bitlines labeled BL when a wordline (WL) is taken “high”;

FIG. 2 illustrates a portion of a representative, conventional folded bitline, shared sense amplifier DRAM array in a configuration that utilizes an adjacent bitline as a reference input to the sense amplifier for the bitline being connected to the memory cell capacitor;

FIG. 3 illustrates a portion of a DRAM architecture in accordance with an embodiment of the present invention which incorporates a folded bitline DRAM with shared sense amplifiers and which uses a bitline in an adjacent subarray as a reference bitline; and

FIG. 4 illustrates a portion of a DRAM architecture in accordance with an embodiment of the present invention in which one sense amplifier band has half the number of sense amplifiers as there are bitlines thereby obviating the need for a dummy end array.

### DESCRIPTION OF A REPRESENTATIVE EMBODIMENT

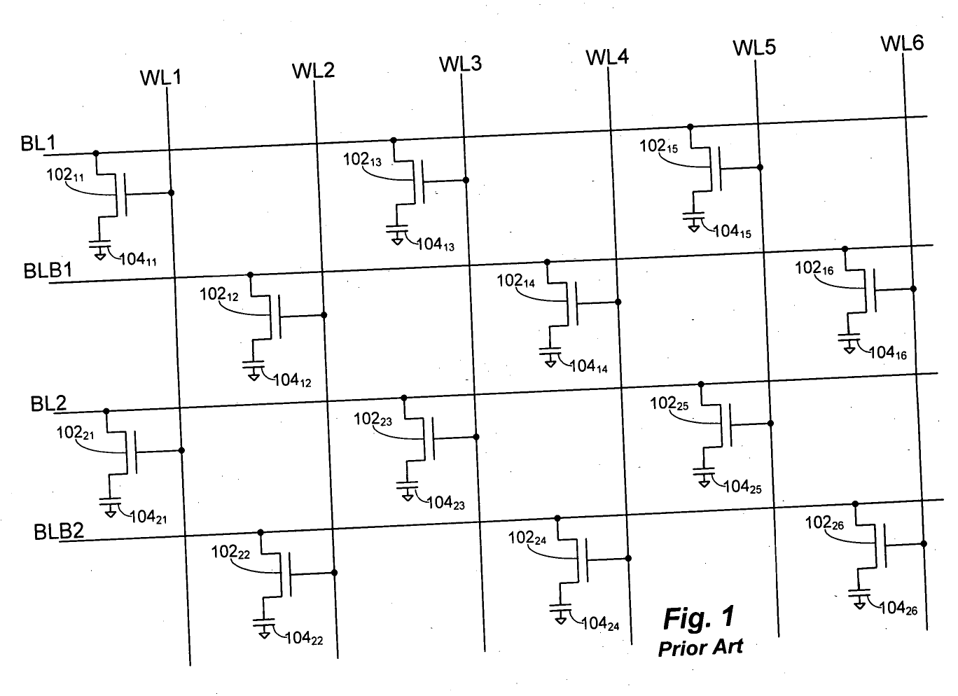

With reference now to FIG. 1, a portion of a representative folded bitline DRAM array 100 is shown in which the bitlines labeled BLB (bitline bar; e.g. BLB1 and BLB2) are available to act as reference inputs to the sense amplifier (not shown) for the bitlines labeled BL (e.g. BL1 and BL2) when a wordline (WL) is taken “high”.

Each of the memory cells of the DRAM array 100 comprise an N-channel access transistor 102₁₁ through 102₁₆ and 102₂₁ through 102₂₆ and an associated storage capacitor 104₁₁ through 104₁₆ and 104₂₁ through 104₂₆ respectively. Each of the transistors 102 has its drain terminal coupled to one of the corresponding complementary bitlines and its gate coupled to one of the wordlines WL1 through WL6. The source terminal of the transistors 102 is coupled one plate of the corresponding capacitor 104 which, in turn, has its other plate coupled to circuit ground (VSS) or a common plate line depending upon the particular memory technology employed.

As stated previously, in the portion of the DRAM array 100 shown, the bitlines labeled BLB are available to act as reference inputs to the sense amplifier for the bitlines labeled BL when a wordline is taken “high”, that is, during a “read”, “write” access or “refresh” operation. If the DRAM array 100 also employs a shared sense amplifier architecture, the bitlines labeled BL1 and BLB1 would be sensed by a sense amplifier on one side of the array and bitlines labeled BL2 and BLB2 would be sensed by a sense amplifier on the other side of the array.

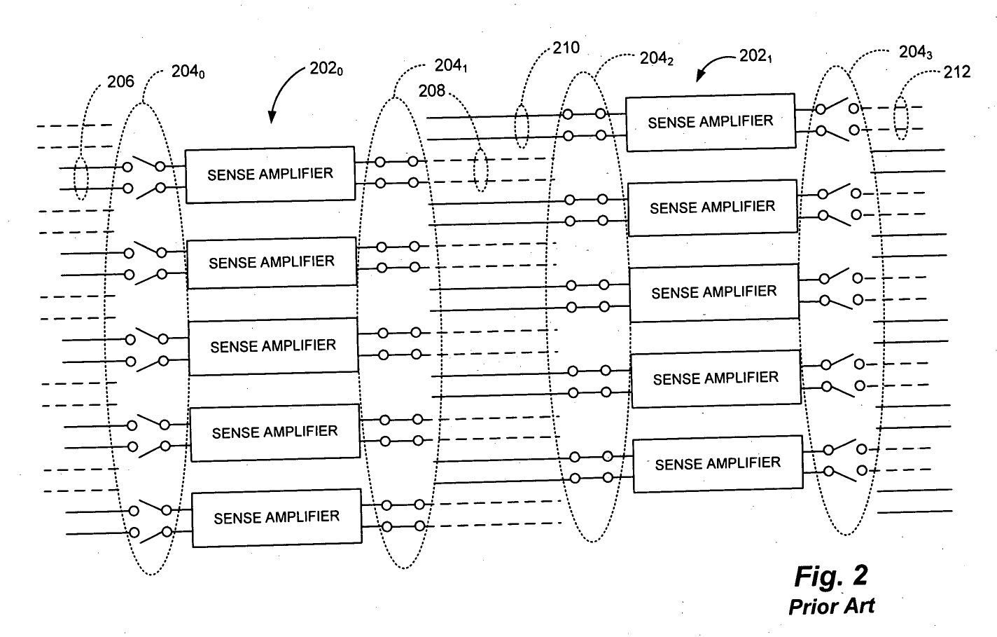

With reference additionally now to FIG. 2, a portion of a representative, conventional folded bitline, shared sense amplifier DRAM array 200 is shown in a configuration that utilizes an adjacent bitline as a reference input to the sense amplifier for the bitline being connected to the memory cell capacitor 104 through a corresponding access transistor 102 (FIG. 1).

The portion of the DRAM array 200 illustrated comprises, in pertinent part, two columns of shared sense amplifiers 202₀ and 202₁. Two pairs of isolation transistors, illustrated for purposes of clarity as simple switches, are associated with each of the sense amplifiers and are illustrated as groupings 204₀ and 204₁ associated with sense amplifiers 202₀ and groupings 204₂ and 204₃ associated with sense amplifiers 202₁. An exemplary pair of complementary bitlines 206 and 210, which are selectively coupled to a right hand one of the sense amplifiers 202₀ and 202₁ through isolation transistors in groupings 204₀ and 204₂, are indicated by solid lines. Correspondingly, an exemplary pair of complementary bitlines 208 and 212, which are selectively coupled to a left hand one of the sense amplifiers 202₀ and 202₁ through isolation transistors in groupings 204₁ and 204₃, are indicated by dashed lines.

For purposes of this illustration, it is assumed that a word line (not shown) has been activated in the center subarray. The isolation transistors are shown in a conventional configuration that utilizes an adjacent bitline as a reference input to the sense amplifier for the bitline being connected to the memory cell capacitor. Thus, in operation, the isolation transistors 204₀ function to disconnect the sense amplifiers 202₀ from, for example, both of the complementary bitlines 206 as well as to disconnect the sense amplifiers 202₁ from both of the complementary bitlines 212 by means of isolation transistors 204₃. Further, the isolation transistors 204₁ couple the sense amplifiers 202₀ to, for example, the bitlines 208 while the isolation transistors 204₂ couple the sense amplifiers 202₁ to the bitlines 210.

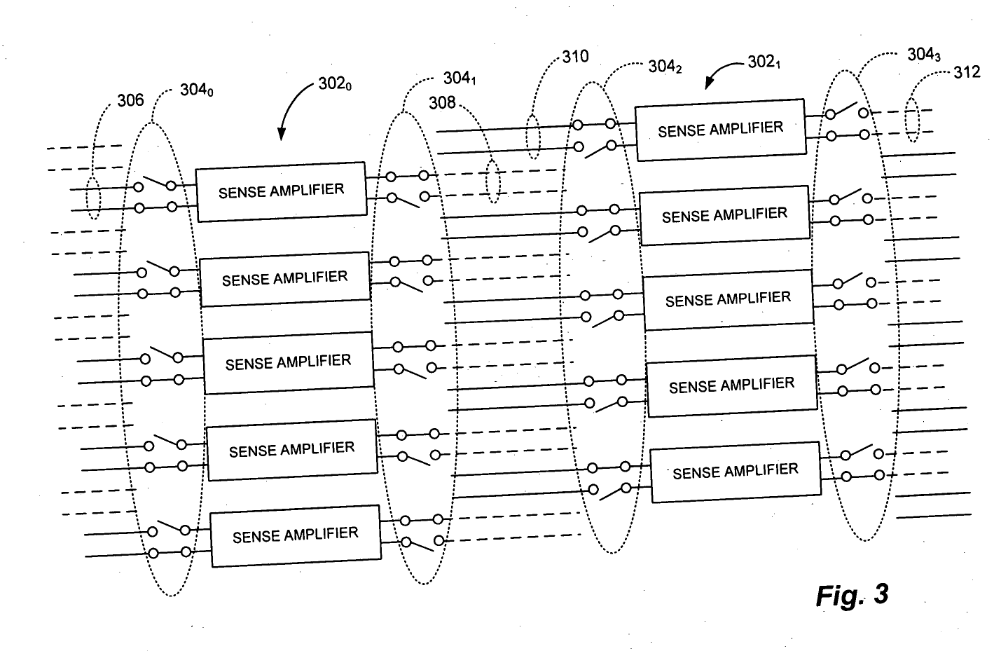

With reference additionally now to FIG. 3, a portion of a DRAM architecture 300 is shown in accordance with an embodiment of the present invention which incorporates a folded bitline DRAM array with shared sense amplifiers and which uses a bitline in an adjacent subarray as a reference bitline.

The portion of the DRAM array 300 comprises, in pertinent part, two columns of shared sense amplifiers 302₀ and 302₁. Two pairs of isolation transistors, again illustrated for purposes of clarity as switches, are associated with each of the sense amplifiers and are illustrated as groupings 304₀ and 304₁ associated with sense amplifiers 302₀ and groupings 304₂ and 304₃ associated with sense amplifiers 302₁. As before, an exemplary pair of complementary bitlines 306 and 310, which are selectively coupled to a right hand one of the sense amplifiers 302₀ and 302₁ through isolation transistors in groupings 304₀ and 304₂, are indicated by solid lines. Correspondingly, an exemplary pair of complementary bitlines 308 and 312, which are selectively coupled to a left hand one of the sense amplifiers 302₀ and 302₁ through isolation transistors in groupings 304₁ and 304₃, are indicated by dashed lines.

In accordance with the present invention, a DRAM architecture is disclosed utilizing a folded bitline structure with shared sense amplifiers which employs a bitline in an adjacent subarray as a reference bitline. Once again, it is assumed that a word line (not shown) has been activated in the center subarray. As can be determined, only alternate bitlines (every second one) will be driven in the center subarray intermediate sense amplifiers 302₀ and 302₁. Also, only every fourth bitline will be driven in the other two subarrays located laterally of the two columns of sense amplifiers 302₀ and 302₁. Since the adjacent bitlines are not driven in the active subarray, it is apparent that adjacent bitline-to-bitline coupling is eliminated by the proposed shielded bitline DRAM architecture.

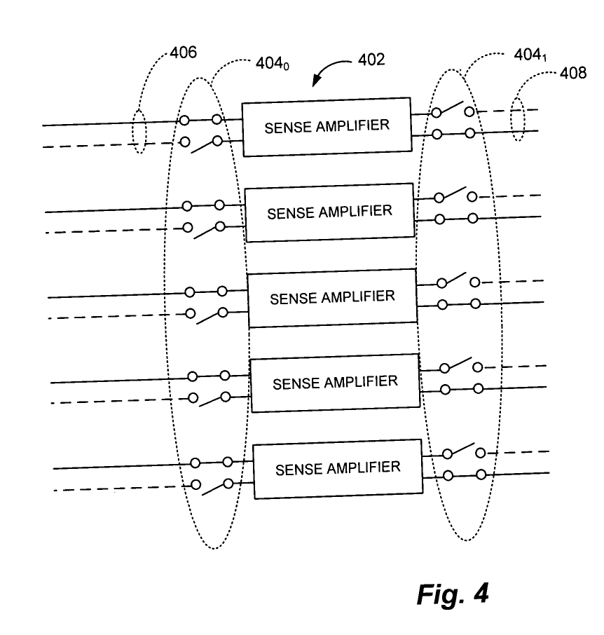

With reference additionally now to FIG. 4, a portion of a DRAM architecture 400 in accordance with another embodiment of the present invention is illustrated in which one sense amplifier band has half the number of sense amplifiers 402 as there are bitlines thereby obviating the need for a dummy end array as may be required in the embodiment of FIG. 3. As before, two pairs of isolation transistors, again illustrated for purposes of clarity as switches, are associated with each of the sense amplifiers 402 and are illustrated as groupings 404₀ and 404₁. Also as before, an exemplary pair of complementary bitlines 406 and 408 may be individually and selectively couplable to one of the sense amplifiers 402 through isolation transistors in these groupings 404₀ and 404₁ respectively. In this figure, active bitlines are indicated by solid lines and corresponding shielding bitlines are indicated by a dashed line.

In this particular embodiment of the present invention, the DRAM architecture 400 allows for all of the bitlines to be able to be attached to the sense amplifiers 402. Thus, the number of sense amplifiers 402 is one half the number of subarrays while the number of sense amplifier bands required in the embodiment of FIG. 3 is the number of subarrays minus one and each sense amplifier band has one fourth the number of sense amplifiers 302 as there are bitlines.

While there have been described above the principles of the present invention in conjunction with a specific dynamic random access memory array architecture, it is to be clearly understood that the foregoing description is made only by way of example and not as a limitation to the scope of the invention. Particularly, it is recognized that the teachings of the foregoing disclosure will suggest other modifications to those persons skilled in the relevant art. Such modifications may involve other features which are already known per se and which may be used instead of or in addition to features already described herein. Although claims have been formulated in this application to particular combinations of features, it should be understood that the scope of the disclosure herein also includes any novel feature or any novel combination of features disclosed either explicitly or implicitly or any generalization or modification thereof which would be apparent to persons skilled in the relevant art, whether or not such relates to the same invention as presently claimed in any claim and whether or not it mitigates any or all of the same technical problems as confronted by the present invention. The applicants hereby reserve the right to formulate new claims to such features and/or combinations of such features during the prosecution of the present application or of any further application derived therefrom.

As used herein, the terms “comprises”, “comprising”, or any other variation thereof, are intended to cover a non-exclusive inclusion, such that a process, method, article, or apparatus that comprises a recitation of certain elements does not necessarily include only those elements but may include other elements not expressly recited or inherent to such process, method, article or apparatus. None of the description in the present application should be read as implying that any particular element, step, or function is an essential element which must be included in the claim scope and THE SCOPE OF THE PATENTED SUBJECT MATTER IS DEFINED ONLY BY THE CLAIMS AS ALLOWED. Moreover, none of the appended claims are intended to invoke paragraph six of 35 U.S.C. Sect. 112 unless the exact phrase “means for” is employed and is followed by a participle.

What is claimed is:

1. An integrated circuit device incorporating a memory array including at least two subarrays of memory cells comprising:
at least one sense amplifier selectively coupleable to a first pair of complementary bitlines in a first one of said subarrays and a second pair of complementary bitlines in a second one of said subarrays, one of said first pair of complementary bitlines being selectively operative as a reference line for one of said second pair of complementary bitlines.

2. The integrated circuit device of claim 1 wherein said first subarray is inactive and said second subarray is active.

3. The integrated circuit device of claim 1 wherein said at least one sense amplifier is selectively coupleable to said first and second pair of complementary bitlines through isolation transistors.

4. The integrated circuit device of claim 1 wherein said first and second pairs of complementary bitlines each comprise parallel BL and /BL lines.

5. The integrated circuit device of claim 4 wherein said one of said first pair of complementary bitlines comprises a BL line and said one of said second pair of complementary bitlines comprises a /BL line.

6. The integrated circuit device of claim 4 wherein said one of said first pair of complementary bitlines comprises a /BL line and said one of said second pair of complementary bitlines comprises a BL line.

7. An integrated circuit device incorporating a memory array including N subarrays of memory cells, wherein N>1 comprising:
a plurality of folded bitline shared sense amplifiers having a first pair of complementary bitlines in an active one of said N subarrays and a second pair of complementary bitlines in an inactive one of said N subarrays; and
first and second pairs of isolation transistors for selectively coupling each of said plurality of shared sense amplifiers to said first and second pairs of complementary bitlines, said isolation transistors being operative to couple each of said plurality of sense amplifiers such that one of said second pair of complementary bitlines serves as a reference for one of said first pair of complementary bitlines.

8. The integrated circuit device of claim 7 wherein said first and second pairs of complementary bitlines each comprise parallel BL and /BL lines.

9. The integrated circuit device of claim 8 wherein said one of said first pair of complementary bitlines comprises a BL line and said one of said second pair of complementary bitlines comprises a /BL line.

10. The integrated circuit device of claim 8 wherein said one of said first pair of complementary bitlines comprises a /BL line and said one of said second pair of complementary bitlines comprises a BL line.

11. An integrated circuit device incorporating a memory array including a plurality of subarrays of memory cells comprising:
first and second columns of sense amplifiers; and
first and second pairs of complementary bitlines being coupleable to each of said sense amplifiers in said first and second columns, said first pairs of said complementary bitlines coupleable to said sense amplifiers of said first column being interleaved with said second pairs of said complementary bitlines coupleable to said sense amplifiers of said second column, said memory array operative to drive every second one of said bitlines in an active one of said plurality of subarrays and every fourth one of said bitlines in adjacent inactive ones of said plurality of subarrays.

12. The integrated circuit device of claim 11 wherein said first and second pairs of complementary bitlines each comprise parallel BL and /BL lines.

13. A method for providing a reference in a folded bitline array of memory cells and shared sense amplifiers comprising:
asserting a wordline in a selected subarray of said memory cells to couple one of said memory cells to an associated bitline coupled to one of said sense amplifiers; and
utilizing another bitline also coupled to said one of said sense amplifiers in an adjacent subarray as a reference for said associated bitline.

14. A method for providing a reference in a folded bitline, shared sense amplifier memory of an integrated circuit device comprising:
driving alternate ones of complementary bitlines in an active subarray of said memory; and
driving fourth ones of said complementary bitlines in an inactive adjacent subarray of said memory.
